(19) United States
(12) Patent Application Publication
(10) Pub. No.: US 2020/0099342 A1
(43) Pub. Date: Mar. 26, 2020

(54) MULTI-MODE HYBRID RADIO FREQUENCY (RF) POWER AMPLIFIER WITH DRIVER AMPLIFIER BYPASS

(71) Applicant: QUALCOMM INCORPORATED, San Diego, CA (US)

(72) Inventors: Yan Kit Gary HAU, Westford, MA (US); Jisun RYU, Sudbury, MA (US); Zhenying LUO, Wayland, MA (US); Xinwei WANG, Dunstable, MA (US); Xiangdong ZHANG, Westford, MA (US)

(21) Appl. No.: 16/137,082

(22) Filed: Sep. 20, 2018

(51) Int. Cl. H03F 1/02; H03F 3/72; H03F 3/21; H03F 3/24; H01L 27/12

(52) U.S. Cl. CPC H03F 1/0277; H03F 3/72; H01L 27/1203; H03F 3/245; H03F 3/211

(57) ABSTRACT

An amplifier circuit includes a driver amplifier implemented on a silicon-on-insulator (SOI) substrate and configured to amplify a radio frequency (RF) signal, a bypass circuit implemented on the SOI substrate and configured to selectively bypass the driver amplifier, an output coupled to the driver amplifier and the bypass circuit, an interconnect configured to couple the output to a gallium arsenide (GaAs) substrate, and a power amplifier implemented on the GaAs substrate and configured to amplify a signal received over the interconnect from the output.

### FIELD

The present disclosure relates generally to electronics, and more specifically to power amplifiers.

### BACKGROUND

In a radio frequency (RF) transceiver, a communication signal is typically amplified and transmitted by a transmit section. A transmit section may comprise one or more circuits that amplify and transmit the communication signal. The amplifier circuit or circuits may comprise one or more amplifier stages that may include one or more driver stages and one or more power amplifier stages. The amplifier circuit or circuits may generally be called upon to provide different levels of power amplification over a wide bandwidth, while attempting to provide both efficiency and linearity. Often, providing a linear power output comes at the expense of efficiency, and providing high efficiency comes at the expense of linearity.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides an amplifier circuit including a driver amplifier implemented on a silicon-on-insulator (SOI) substrate and configured to amplify a radio frequency (RF) signal, a bypass circuit implemented on the SOI substrate and configured to selectively bypass the driver amplifier, an output coupled to the driver amplifier and the bypass circuit, an interconnect configured to couple the output to a gallium arsenide (GaAs) substrate, and a power amplifier implemented on the GaAs substrate and configured to amplify a signal received over the interconnect from the output.

Another aspect of the disclosure provides a method for communication including in a first mode, amplifying a first communication signal using a driver amplifier on a silicon-on-insulator (SOI) substrate, providing the amplified first communication signal over an interconnect, and further amplifying the amplified first communication signal using a power amplifier on a gallium arsenide (GaAs) substrate, and in a second mode, bypassing the driver amplifier to provide a second communication signal over the interconnect and amplifying the second communication signal using the power amplifier to the exclusion of the driver amplifier.

Another aspect of the disclosure provides a device including first amplifying means implemented on a silicon-on-insulator (SOI) substrate for amplifying an RF signal, means for selectively bypassing the first amplifying means, means for controlling the bypass means, first coupling means for coupling an output to the first amplifying means and the means for selectively bypassing, second coupling means for coupling the output to a gallium arsenide (GaAs) substrate, and second amplifying means implemented on the GaAs substrate for amplifying a communication signal received over the second coupling means.

Another aspect of the disclosure provides an amplifier including a first amplifier circuit implemented on a first substrate and configured to selectively amplify a radio frequency (RF) signal in a first power mode, a bypass circuit implemented on the first substrate and configured to bypass the first amplifier circuit in a second power mode, the second power mode operative to output a signal with lower power, a shared output coupled to the first amplifier circuit and the bypass circuit, a shared interconnect configured to couple the output to a second substrate, and a shared second amplifier circuit implemented on a second substrate, the second amplifier circuit being configured to amplify the RF signal in the first power mode and the second power mode.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a graphical diagram showing an example of contiguous intra-band carrier-aggregation (CA).

FIG. 2B is a graphical diagram showing an example of non-contiguous intra-band CA.

FIG. 2C is a graphical diagram showing an example of inter-band CA in the same band group.

FIG. 2D is a graphical diagram showing an example of inter-band CA in different band groups.

FIG. 3 is a block diagram showing a wireless device in which the exemplary techniques of the present disclosure may be implemented.

FIG. 4 is a block diagram illustrating an amplifier circuit in accordance with an exemplary embodiment of the disclosure.

FIG. 5 is a block diagram illustrating an amplifier circuit in accordance with an exemplary embodiment of the disclosure.

FIG. 6 is a block diagram illustrating an amplifier circuit in accordance with an exemplary embodiment of the disclosure.

FIG. 7 is a schematic diagram illustrating an amplifier circuit in accordance with an exemplary embodiment of the disclosure.

FIG. 8 is a flow chart describing the operation of an exemplary embodiment of an amplifier circuit in accordance with an exemplary embodiment of the disclosure.

FIG. 9 is a functional block diagram of an apparatus for an amplifier circuit in accordance with an exemplary embodiment of the disclosure.

FIG. 10 is a flow chart describing the operation of an exemplary embodiment of an amplifier circuit in accordance with an exemplary embodiment of the disclosure.

FIG. 11 is a functional block diagram of an apparatus for an amplifier circuit in accordance with an exemplary embodiment of the disclosure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

Exemplary embodiments of the disclosure are directed to a multi-mode hybrid radio frequency (RF) power amplifier with driver amplifier bypass that can be configured to bypass a driver amplifier stage in an ultra-low power mode (ULPM) such that only a main power amplifier provides signal amplification in the ULPM. In an exemplary embodiment, the multi-mode hybrid radio frequency (RF) power amplifier can also provide signal amplification in high power mode (HPM)/low power mode (LPM) (HPM/LPM) by using both a driver amplifier and a power amplifier to provide signal amplification.

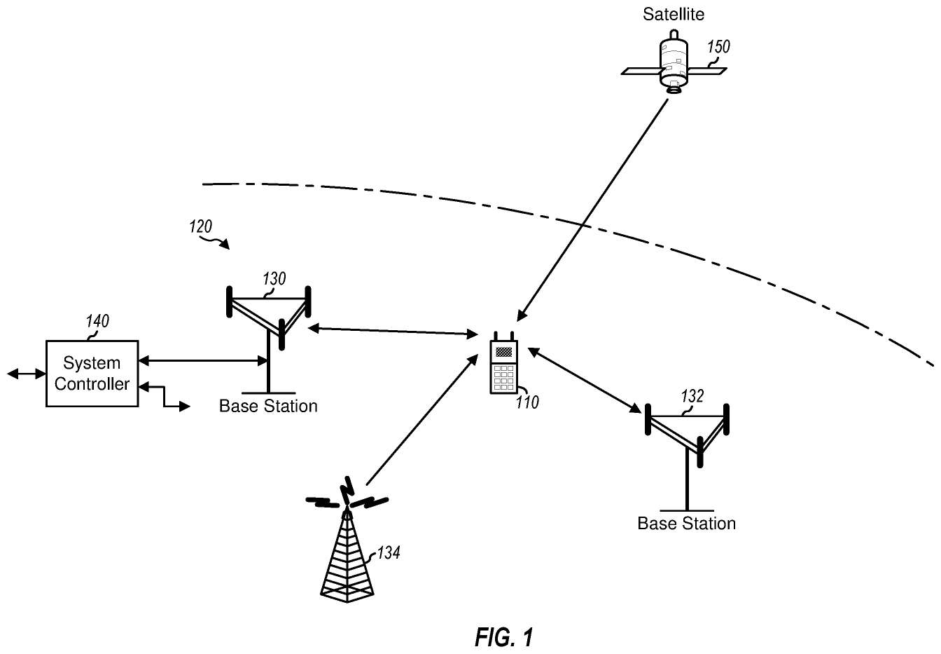

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1X, EVDO, TD-SCDMA, GSM, 802.11, 5G, etc.

Wireless device 110 may support carrier aggregation, for example as defined in an LTE standard. Wireless device 110 may be able to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz and 3400 to 3800 MHz. Low-band, mid-band, and high-band refer to three groups of bands (or band groups), with each band group including a number of frequency bands (or simply, “bands”). Each band may cover up to 200 MHz and may include one or more carriers, and each carrier may cover up to 20 MHz in LTE. LTE Release 11 supports 35 bands, which are referred to as LTE/UMTS bands and are listed in 3GPP TS 36.101. Wireless device 110 may be configured with up to five carriers in one or two bands in LTE Release 11. Other band configurations or configurations pursuant to a standard other than LTE or pursuant to an LTE release different than discussed herein may also be used and/or implemented.

In general, carrier aggregation (CA) may be categorized into two types: intra-band CA and inter-band CA. Intra-band CA refers to operation on multiple carriers within the same band. Inter-band CA refers to operation on multiple carriers in different bands.

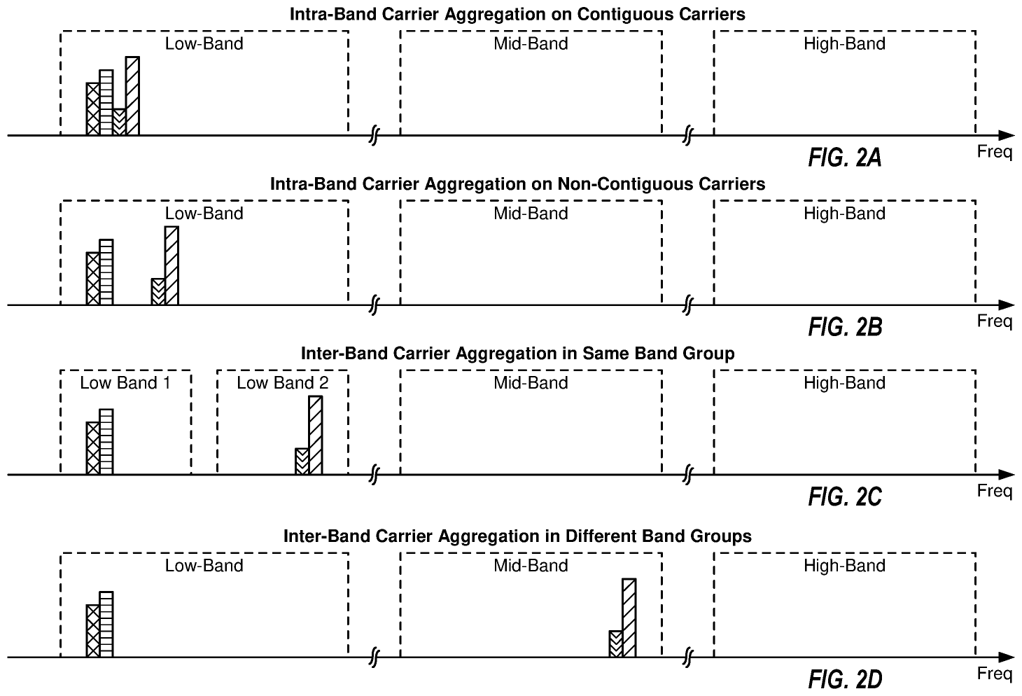

FIG. 2A is a graphical diagram showing an example of contiguous intra-band carrier-aggregation (CA). In the example shown in FIG. 2A, wireless device 110 is configured with four contiguous carriers in one band in low-band. Wireless device 110 may send and/or receive transmissions on the four contiguous carriers within the same band.

FIG. 2B is a graphical diagram showing an example of non-contiguous intra-band CA. In the example shown in FIG. 2B, wireless device 110 is configured with four non-contiguous carriers in one band in low-band. The carriers may be separated by 5 MHz, 10 MHz, or some other amount. Wireless device 110 may send and/or receive transmissions on the four non-contiguous carriers within the same band.

FIG. 2C is a graphical diagram showing an example of inter-band CA in the same band group. In the example shown in FIG. 2C, wireless device 110 is configured with four carriers in two bands in low-band. Wireless device 110 may send and/or receive transmissions on the four carriers in different bands in the same band group.

FIG. 2D is a graphical diagram showing an example of inter-band CA in different band groups. In the example shown in FIG. 2D, wireless device 110 is configured with four carriers in two bands in different band groups, which include two carriers in one band in low-band and two carriers in another band in mid-band. Wireless device 110 may send and/or receive transmissions on the four carriers in different bands in different band groups.

FIGS. 2A to 2D show four examples of carrier aggregation. Carrier aggregation may also be supported for other combinations of bands and band groups.

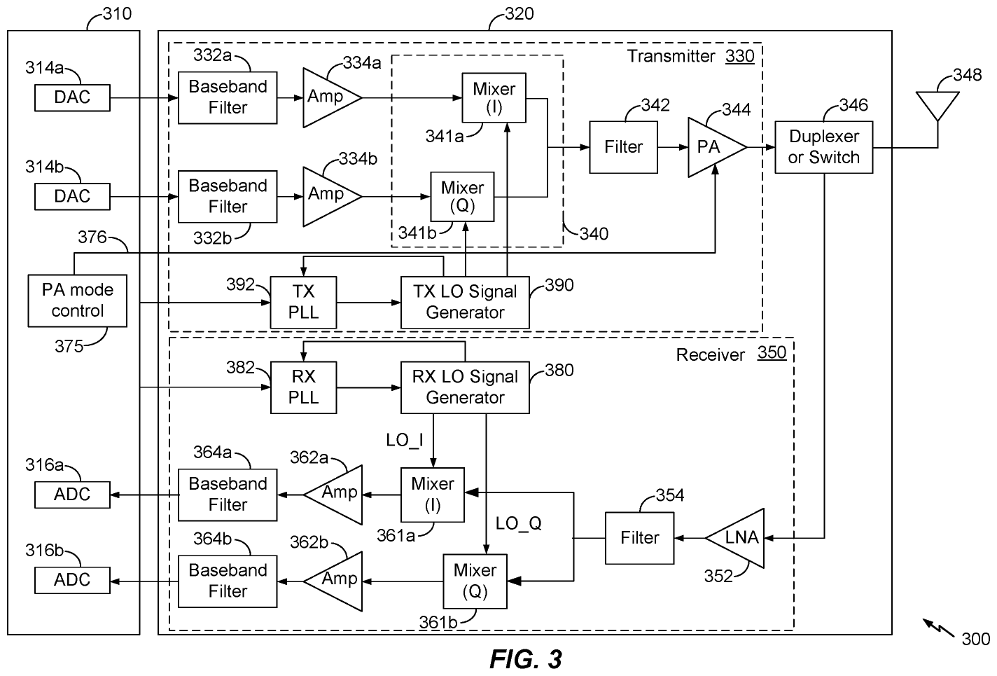

FIG. 3 is a block diagram showing a wireless device 300 in which the exemplary techniques of the present disclosure may be implemented. FIG. 3 shows an example of a transceiver 320. In general, the conditioning of the signals in a transmitter 330 and a receiver 350 may be performed by one or more stages of amplifier, filter, upconverter, downconverter, etc. These circuit blocks may be arranged differently from the configuration shown in FIG. 3. Furthermore, other circuit blocks not shown in FIG. 3 may also be used to condition the signals in the transmitter 330 and receiver 350. Unless otherwise noted, any signal in FIG. 3, or any other figure in the drawings, may be either single-ended or differential. Some circuit blocks in FIG. 3 may also be omitted.

In the example shown in FIG. 3, wireless device 300 generally comprises a transceiver 320 and a data processor 310. The data processor 310 may include a memory (not shown) to store data and program codes, and may generally comprise analog and digital processing elements. The transceiver 320 includes a transmitter 330 and a receiver 350 that support bi-directional communication. In general, wireless device 300 may include any number of transmitters and/or receivers for any number of communication systems and frequency bands. All or a portion of the transceiver 320 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 3, transmitter 330 and receiver 350 are implemented with the direct-conversion architecture.

In the transmit path, the data processor 310 processes data to be transmitted and provides in-phase (I) and quadrature (Q) analog output signals to the transmitter 330. In an exemplary embodiment, the data processor 310 includes digital-to-analog-converters (DAC's) 314a and 314b for converting digital signals generated by the data processor 310 into the I and Q analog output signals, e.g., I and Q output currents, for further processing. In other embodiments, the DACs 314a and 314b are included in the transceiver 320 and the data processor 310 provides data (e.g., for I and Q) to the transceiver 320 digitally.

Within the transmitter 330, lowpass filters 332a and 332b filter the I and Q analog transmit signals, respectively, to remove undesired images caused by the prior digital-to-analog conversion Amplifiers (Amp) 334a and 334b amplify the signals from lowpass filters 332a and 332b, respectively, and provide I and Q baseband signals. An upconverter 340 upconverts the I and Q baseband signals with I and Q transmit (TX) local oscillator (LO) signals from a TX LO signal generator 390 and provides an upconverted signal. A filter 342 filters the upconverted signal to remove undesired images caused by the frequency upconversion as well as noise in a receive frequency band. A power amplifier (PA) 344 amplifies the signal from filter 342 to obtain the desired output power level and provides a transmit RF signal. The transmit RF signal is routed through a duplexer or switch 346 and transmitted via an antenna 348.

In the receive path, antenna 348 receives communication signals and provides a received RF signal, which is routed through duplexer or switch 346 and provided to a low noise amplifier (LNA) 352. The duplexer 346 is designed to operate with a specific RX-to-TX duplexer frequency separation, such that RX signals are isolated from TX signals. The received RF signal is amplified by LNA 352 and filtered by a filter 354 to obtain a desired RF input signal. Downconversion mixers 361a and 361b mix the output of filter 354 with I and Q receive (RX) LO signals (i.e., LO_I and LO_Q) from an RX LO signal generator 380 to generate I and Q baseband signals. The I and Q baseband signals are amplified by amplifiers 362a and 362b and further filtered by lowpass filters 364a and 364b to obtain I and Q analog input signals, which are provided to data processor 310. In the exemplary embodiment shown, the data processor 310 includes analog-to-digital-converters (ADC's) 316a and 316b for converting the analog input signals into digital signals to be further processed by the data processor 310. In some embodiments, the ADCs 316a and 316b are included in the transceiver 320 and provide data to the data processor 310 digitally.

In FIG. 3, TX LO signal generator 390 generates the I and Q TX LO signals used for frequency upconversion, while RX LO signal generator 380 generates the I and Q RX LO signals used for frequency downconversion. Each LO signal is a periodic signal with a particular fundamental frequency. A phase locked loop (PLL) 392 receives timing information from data processor 310 and generates a control signal used to adjust the frequency and/or phase of the TX LO signals from LO signal generator 390. Similarly, a PLL 382 receives timing information from data processor 310 and generates a control signal used to adjust the frequency and/or phase of the RX LO signals from LO signal generator 380.

Wireless device 300 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain elements of the transceiver 320 are functionally illustrated in FIG. 3, and the configuration illustrated therein may or may not be representative of a physical device configuration in certain implementations. For example, as described above, transceiver 320 may be implemented in various integrated circuits (ICs), RF ICs (RFICs), mixed-signal ICs, etc. In some embodiments, the transceiver 320 is implemented on a substrate or board such as a printed circuit board (PCB) having various modules. For example, the PA 344, the filter 342, and the duplexer 346 may be implemented in separate modules or as discrete components, while the remaining elements illustrated in the transceiver 320 may be implemented in a single transceiver chip.

The power amplifier 344 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 344 can be configured to operate using one or more driver stages, one or more power amplifier stages, one or more impedance matching networks, and can be configured to use a single output path, that may comprise a single output matching network and a single output switch circuit to provide an amplified communication signal output. In some embodiments, a common output path including a common PA, common output matching network, and common switch circuit is shared between a plurality of transmission modes, for example an HPM and an ULPM. In an exemplary embodiment, the transmission mode or modes may be selected by, or determined by, a PA mode control circuit 375 that may be located in the data processor 310, or elsewhere. The PA mode control circuit 375 or the data processor 310 may provide a mode control signal over connection 376 to the PA 344 to determine the amplification mode of the PA 344.

In an exemplary embodiment of the present disclosure, a multi-mode hybrid radio frequency (RF) power amplifier with driver amplifier bypass may be incorporated with or into the power amplifier 344 to provide RF power amplification. In a particular exemplary embodiment, a multi-mode hybrid radio frequency (RF) power amplifier with driver amplifier bypass may be configured to provide one or more power amplification levels that increase linearity and efficiency. Those of skill in the art, however, will recognize that aspects of the a multi-mode hybrid radio frequency (RF) power amplifier with driver amplifier bypass described herein may be implemented in transmit architectures which differ from the architecture illustrated in FIG. 3 and may be implemented in other devices in which RF power amplification is desired.

The power amplifier 344 may comprise one or more driver and amplifier stages. Some or all of these stages may be implemented with one or more technologies and processes, such as, for example, complementary metal oxide semiconductor (CMOS), N-channel MOS (NMOS), P-channel MOS (PMOS), bipolar junction transistor (BJT), bipolar-CMOS (BiCMOS), heterojunction bipolar transistors (HBTs), high electron mobility transistors (HEMTs), silicon germanium (SiGe), gallium arsenide (GaAs), gallium nitride (GaN), silicon-on-insulator (SOI), etc.

Moreover, embodiments of the multi-mode hybrid radio frequency (RF) power amplifier with driver amplifier bypass device may comprise the power amplifier 344 or may be integrated within the power amplifier 344.

It is generally desirable for a power amplifier circuit to provide linear power amplification over a desired bandwidth, which may be a wide bandwidth, support high data rate transmission, provide high efficiency over the desired power output range and bandwidth, and support multiple power modes, including, for example, high power mode (HPM), low power mode (LPM) and ultra-low power mode (ULPM). In an exemplary embodiment for ULPM, it is desirable for the power amplifier to have a low gain (on the order of about 10 dB), contribute low receive band noise, and have low current consumption. In an exemplary embodiment, ULPM may comprise power levels on the order of less than 9 dBm, LPM may comprise power levels on the order of approximately 9 dBm to approximately 19 dBm, and HPM may comprise power levels on the order of approximately 19 dBm to approximately 29 dBm.

Existing power amplifier architectures that support an ULPM may have a parallel design, in which the ULPM power amplifier is implemented as an additional and separate amplifier alongside a main amplifier, using an additional matching network, either using the same manufacturing process for both the ULPM power amplifier and the main power amplifier or using different manufacturing processes for the ULPM power amplifier and the main power amplifier. Unfortunately, this type of architecture adds complexity and cost. It would be desirable to have a way of implementing a power amplifier circuit having an ULPM that is efficient and cost-effective.

In accordance with an exemplary embodiment, a multi-mode hybrid RF power amplifier circuit may include a driver amplifier and a driver amplifier bypass circuit located on a silicon-on-insulator (SOI) substrate, and a power amplifier circuit located on another substrate, such as a gallium arsenide (GaAs) substrate.

In an exemplary embodiment, in an ultra-low power mode (ULPM), the driver amplifier may be bypassed and the main power amplifier used to amplify the transmission signal using the output of a DC-DC converter to provide a DC supply voltage to the output of the power amplifier in ULPM mode. In an exemplary embodiment, in the ULPM, an interstage matching network located between the driver amplifier and the power amplifier may also be bypassed and disabled, thus minimizing signal loss and simplifying the amplifier circuit when configured in ULPM.

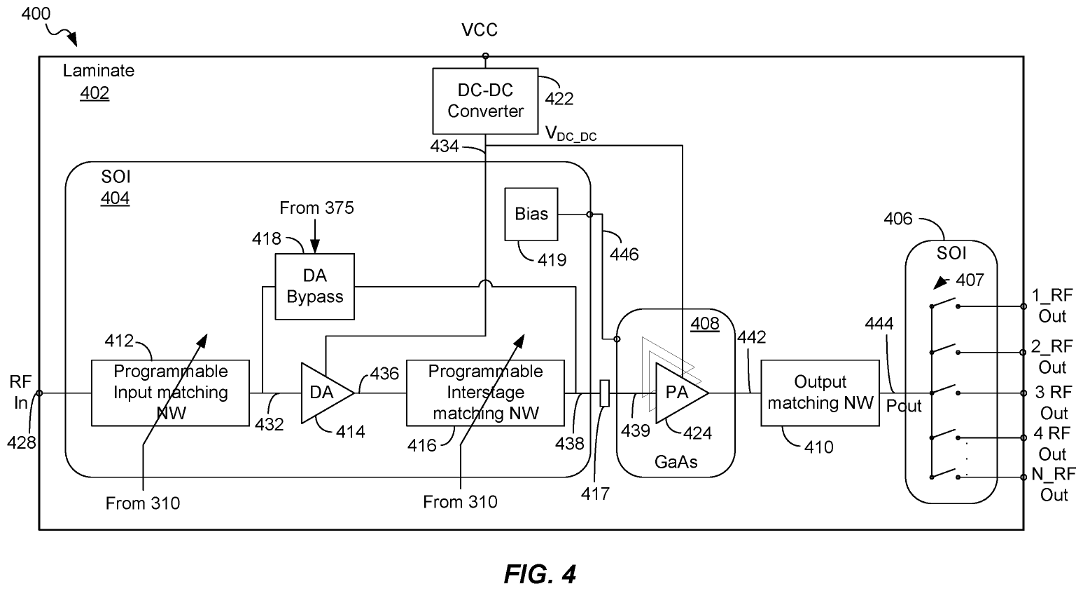

FIG. 4 is a schematic diagram illustrating an amplifier circuit 400 in accordance with an exemplary embodiment of the disclosure. In an exemplary embodiment, the amplifier circuit 400 comprises a laminate 402 on which one or more structures may be formed, fabricated, or otherwise integrated. For example, in an exemplary embodiment, the laminate 402 may comprise a silicon-on-insulator (SOI) substrate 404, a SOI substrate 406, a GaAs substrate 408, an output matching network 410 and a DC-DC converter 422. In an exemplary embodiment, the SOI substrate 404 comprises a programmable input matching network 412, a driver amplifier (DA) 414, a programmable interstage matching network 416, a driver amplifier (DA) bypass circuit 418 and a system bias circuit 419. In an exemplary embodiment, the GaAs substrate 408 comprises a power amplifier 424 having at least one stage, and optionally more than one stage, with the optional additional stages being illustrated using lighter weight line representations of the power amplifier 424 to illustrate one or more stages of the power amplifier 424. The power amplifier 424 may also be referred to as a main power amplifier. While shown as being located on the laminate 402, the DC-DC converter 422 may be located elsewhere, with the output of the DC-DC converter 422 being provided to the SOI substrate 404 and the GaAs substrate 408 as shown in FIG. 4.

In an exemplary embodiment, the SOI substrate 406 may comprise an output band select switch circuit 407 having one or more switches. In an exemplary embodiment, the output band select switch circuit 407 may comprise a plurality of switches corresponding to different output frequency bands, shown in FIG. 4 as “N” frequency bands with the “Nth” frequency band separated from the fourth frequency band by an ellipses, of the amplifier circuit 400, with all instances of switches in the output band select switch circuit 407 receiving the amplified signal output, Pout, from the output matching network 410 over connection 444. The laminate 402, and components implemented thereon, may be configured to implement the PA 344 illustrated in FIG. 3. In some embodiments, a subset of such components may be utilized to implement the PA 344. For example, in some such embodiments, SOI substrate 404 and GaAs substrate 408, and components thereof, may be used to implement the PA 344 while the SOI substrate 406 is used to implement the switch 346.

Returning to the description of FIG. 4, a radio frequency (RF) input signal (for example, as received from the filter 342 or otherwise from the mixers 341 when the filter 342 is omitted) may be provided over connection 428 to the programmable input matching network 412. The output of the programmable input matching network 412 is provided over connection 432 to the DA 414 and to the driver amplifier (DA) bypass circuit 418. The DC-DC converter 422 provides a DC supply voltage, V_{DC_DC}, to the DA 414 and to the power amplifier 424 over connection 434. The output of the DA 414 is provided to the programmable interstage matching network 416 over connection 436. The output of the programmable interstage matching network 416 is provided to an interstage matching network 417 over connection 438. In an exemplary embodiment, the interstage matching network 417 is non-programmable and may comprise one or more components configured to couple the output of the programmable interstage matching network 416 to the input of the power amplifier 424. The output of the interstage matching network 417 is provided to the power amplifier 424 over connection 439. The output of the driver amplifier (DA) bypass circuit 418 is also provided to the power amplifier 424 through the interstage matching network 417 via connections 438 and 439. In an exemplary embodiment, the connections 438 and 439 may comprise a circuit trace, an interconnect, or another connection between the SOI substrate 404 and the GaAs substrate 408. In this way, the connections 438 and 439, and the interstage matching network 417, are common or shared between the path comprising the DA 414/programmable interstage matching network 416 and the path comprising the DA bypass circuit 418. Similarly, the PA 424 and all components of the GaAs substrate 408 may be shared by these two paths.

The output of the power amplifier 424 is provided to the output matching network 410 over connection 442. The output of the output matching network 410 is provided to the output band select switch circuit 407 over connection 444. The system bias circuit 419 may provide one or more bias signals to one or more elements on the SOI substrate 404, and to one or more elements on the GaAs substrate 408, including to the power amplifier 424 over connection 446. In other implementations, the bias circuit 419 may be implemented in a location other than on the SOI substrate 404.

In an exemplary embodiment, the amplifier circuit 400 may be referred to as a “hybrid” amplifier circuit because some portions of the amplifier circuit 400 may be fabricated using SOI and other portions of the amplifier circuit 400 may be fabricated using another process, such as, for example, GaAs, as described herein.

In an exemplary embodiment, the programmable input matching network 412 and the programmable interstage matching network 416 may comprise one or more banks of switchable capacitances arranged in one or more of a series configuration, a parallel configuration, or a combination of a series configuration and parallel configuration, depending on implementation. The programmable input matching network 412 and the programmable interstage matching network 416 may be programmed or controlled by one or more control signals from the data processor 310 (e.g., PA mode control circuit 375) (FIG. 3). In an exemplary embodiment, the control signal provided to the programmable input matching network 412 and to the programmable interstage matching network 416 may comply with the mobile industry processor interface (MIPI) communication protocol and interface.

In an exemplary embodiment, the driver amplifier 414 and the power amplifier 424 have different input impedances, so that the programmable input matching network 412 may be configured to maintain acceptable input return loss and minimize impedance mismatch loss for the driver amplifier 414 in LPM/HPM, and may be configured to maintain acceptable input return loss and minimize impedance mismatch loss for the power amplifier 424 in ULPM, when the driver amplifier 414 and the programmable interstage matching network 416 are bypassed, as will be described herein.

The output matching network 410 may comprise a circuit arrangement that can provide or be configured to provide an appropriate impedance at the output of the power amplifier 424. Moreover, a single instance of the output matching network 410 and a single instance of the output band select switch circuit 407 can provide the amplified signal at all power level outputs of the amplifier circuit 400. Thus, separate matching networks and/or switches aren't needed to support the such power level outputs.

HPM/LPM

In an exemplary embodiment, the amplifier circuit 400 may be configured in multiple different modes to provide different levels of output power. In an exemplary embodiment, the amplifier circuit 400 may be configured in a high power mode (HPM) and/or low power mode (LPM), in which the driver amplifier 414 and the power amplifier 424 are engaged to provide amplification in LPM or in HPM, for example, by biasing the devices in the driver amplifier 414 and the power amplifier 424 appropriately. In the HPM/LPM, the programmable input matching network 412 may be configured to provide an input capacitance selected to optimize the impedance at the input of the driver amplifier 414 on connection 432. In an exemplary embodiment, the programmable interstage matching network 416 may be configured to provide a capacitance selected to optimize the impedance at the output of the driver amplifier 414 on connection 436, and, in conjunction with the non-programmable interstage matching network 417, provide a capacitance selected to optimize the impedance at the input of the power amplifier 424 on connection 439. In an exemplary embodiment, the output matching network 410 may comprise a circuit arrangement that can provide or be configured to provide an appropriate impedance at the output of the power amplifier 424 on connection 442.

ULPM

In an exemplary embodiment, the amplifier circuit 400 may be configured in an ultra-low power mode (ULPM), in which the driver amplifier 414 and the programmable interstage matching network 416 are bypassed, and the power amplifier 424 is engaged to provide amplification without the DA 414 being used. In the ULPM, the driver amplifier 414 and the programmable interstage matching network 416 are disabled, and the driver amplifier 414 and the programmable interstage matching network 416 are bypassed using the DA bypass circuit 418. In an exemplary embodiment, the driver amplifier 414 and the programmable interstage matching network 416 may be disabled by, for example, appropriately biasing devices within the driver amplifier 414 and the programmable interstage matching network 416, removing power from the driver amplifier 414 and the programmable interstage matching network 416, or otherwise disabling the driver amplifier 414 and the programmable interstage matching network 416. In an exemplary embodiment, the DA bypass circuit 418 may be controlled by a signal from the data processor 310 (e.g., PA mode control circuit 375) (FIG. 3) and the programmable interstage matching network 416 may be controlled by a control signal from the data processor 310 (e.g., PA mode control circuit 375) (FIG. 3). In the ULPM, the programmable input matching network 412, in conjunction with the interstage matching network 417 (which may be non-programmable), may be configured to provide a capacitance selected to optimize the impedance at the input of the power amplifier 424 on connection 439. In the ULPM, the programmable interstage matching network 416 is disabled and is configured as an open circuit such that signal leakage from the programmable interstage matching network 416 is reduced or eliminated. In an exemplary embodiment, the output matching network 410 may comprise a circuit arrangement that can provide or be configured to provide an appropriate impedance at the output of the power amplifier 424 on connection 442. In an exemplary embodiment, in the ultra-low power mode (ULPM), the DC-DC converter 422 can be leveraged to provide a low DC supply voltage to the output of the power amplifier 424, which translates to a low current consumption, at ultra-low power levels.

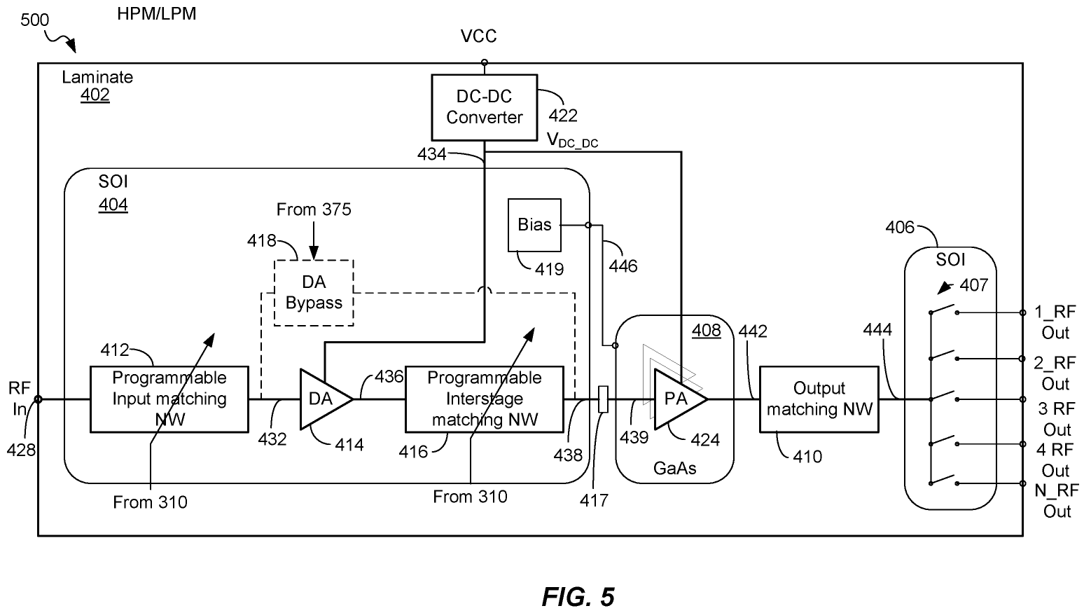

FIG. 5 is a schematic diagram illustrating an amplifier circuit 500 in accordance with an exemplary embodiment of the disclosure. In an exemplary embodiment, the amplifier circuit 500 is similar to the amplifier circuit 400 of FIG. 4; however, in FIG. 5, the amplifier circuit 500 is depicted as being configured for HPM/LPM operation. In accordance with an exemplary embodiment, the driver amplifier (DA) bypass circuit 418 is shown in dotted line to indicate that it is inactive, such that the DA 414 and the power amplifier 424 operate to amplify the RF input signal provided on connection 428.

In an exemplary embodiment, the programmable input matching network 412 may be configured to provide a capacitance selected to optimize the impedance at the driver amplifier 414 on connection 432. In an exemplary embodiment, the programmable interstage matching network 416 may be configured to provide a capacitance selected to optimize the impedance at the output of the driver amplifier 414 on connection 436 and, in conjunction with the non-programmable interstage matching network 417, may be configured to provide a capacitance selected to optimize the impedance at the input of the power amplifier 424 on connection 439. In an exemplary embodiment, the output matching network 410 may comprise a circuit arrangement that can provide or be configured to provide an appropriate impedance at the output of the power amplifier 424.

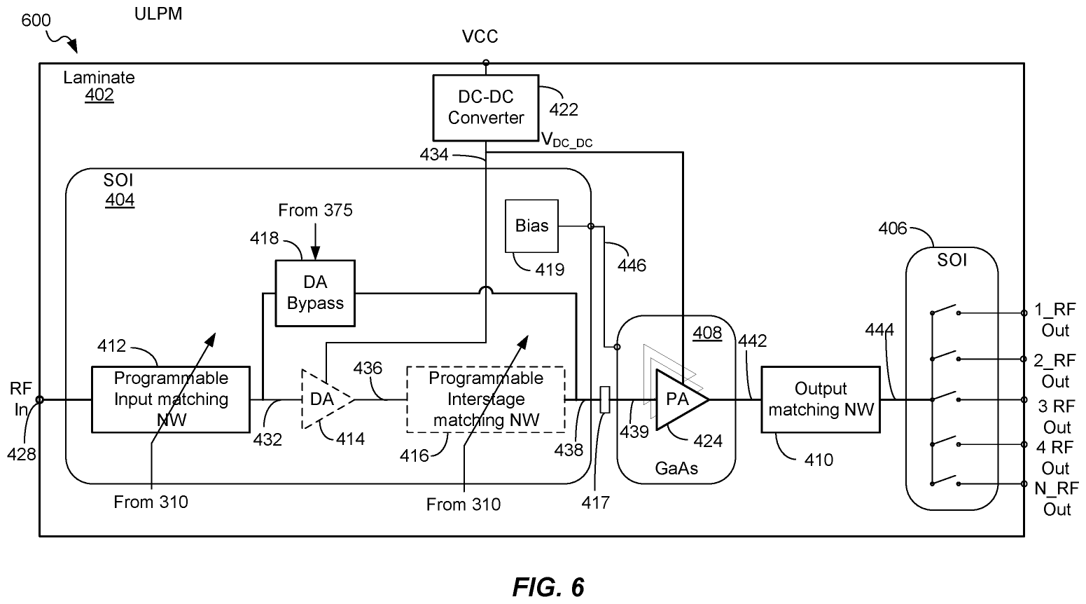

FIG. 6 is a schematic diagram illustrating an amplifier circuit 600 in accordance with an exemplary embodiment of the disclosure. In an exemplary embodiment, the amplifier circuit 600 is similar to the amplifier circuit 400 of FIG. 4; however, in FIG. 6, the amplifier circuit 600 is depicted as being configured for ULPM operation. In accordance with an exemplary embodiment, the driver amplifier (DA) bypass circuit 418 is shown in solid line to indicate that it is active, or enabled by a control signal from, for example, the data processor 310 (e.g., PA mode control circuit 375) (FIG. 3), and the driver amplifier 414 and programmable interstage matching network 416 are shown in dotted line to indicate that they are inactive and bypassed, such that the power amplifier 424 operates to amplify the RF input signal provided on connection 428 in exclusion of the DA 414. In an exemplary embodiment, the programmable input matching network 412, in conjunction with the interstage matching network 417 (which may be non-programmable), may be configured to provide a capacitance selected to optimize the impedance at the input of the power amplifier 424 on connection 439. In the ULPM, the programmable interstage matching network 416 is disabled and configured as an open circuit such that signal leakage from the programmable interstage matching network 416 is reduced or eliminated. In an exemplary embodiment, the output matching network 410 may comprise a circuit arrangement that can provide or be configured to provide an appropriate impedance at the output of the power amplifier 424 on connection 442.

In an exemplary embodiment, because the DA 414 is bypassed in ULPM, both the HPM/LPM and the ULPM share the same output path, which is the output matching network 410 and the output band select switch circuit 407, to provide the amplified signal at all power level outputs of the amplifier circuit 400, 500 and 600.

In an exemplary embodiment, in the ultra-low power mode (ULPM), the DC-DC converter 422 can be leveraged to provide a low DC supply voltage to the output of the power amplifier 424, which translates to a low current consumption, at ultra-low power levels.

In an exemplary embodiment, a technique referred to as average power tracking (APT) may be used to reduce the voltage output of the DC-DC converter 422 based on the average output power of the power amplifier 424 (instead of tracking the instantaneous peak power used in envelope tracking). This APT technique may be used to maximize the efficiency of the amplifier circuit by reducing current consumption of the power amplifier 424 at low power output levels, such as in ULPM.

In another exemplary embodiment, the output voltage of the DC-DC converter 422 can be reduced at any power level other than the maximum power level. Therefore, APT can also be implemented in HPM/LPM, when the power output of the amplifier circuit 400 enters a backoff power level from a maximum power level.

Regardless of the power mode, the embodiments of the amplifier circuits 400, 500 and 600 all share the output matching network 410 and the output band select switch circuit 407 to provide the amplified signal at multiple power level outputs, for example in the described HPM or LPM and in ULPM, of the amplifier circuits 400, 500 and 600.

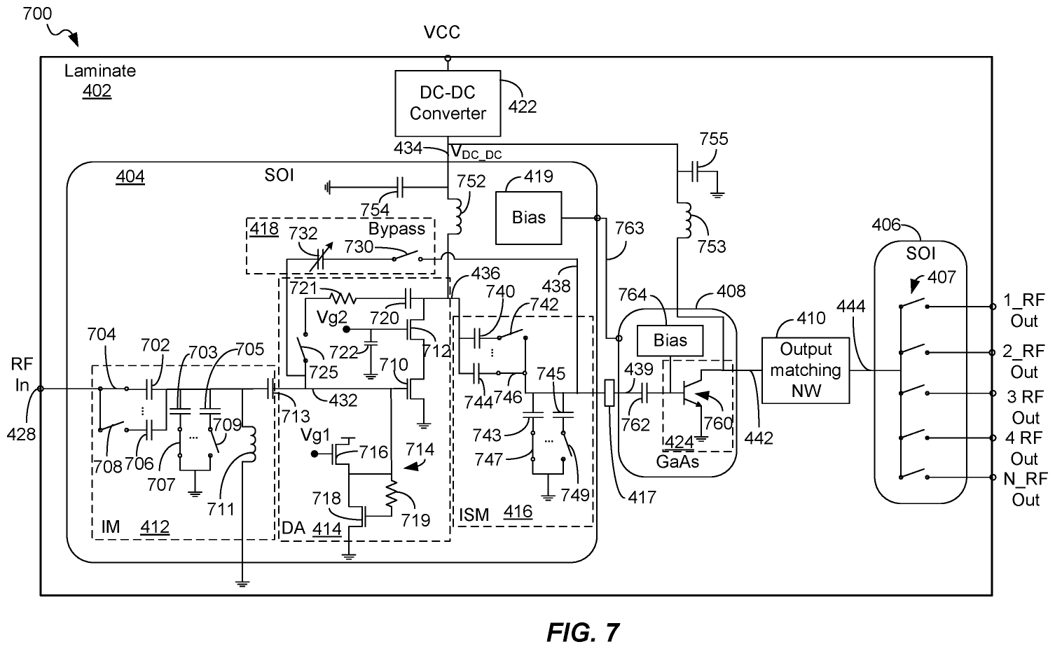

FIG. 7 is a schematic diagram illustrating an amplifier circuit 700 in accordance with an exemplary embodiment of the disclosure. In an exemplary embodiment, the amplifier circuit 700 is a more detailed view of the amplifier circuits 400, 500 and 600 of FIG. 4, FIG. 5 and FIG. 6, respectively.

The amplifier circuit 700 shows the programmable input matching network 412 as comprising one or more switchable series capacitances and one or more switchable parallel capacitances. In an exemplary embodiment, the programmable input matching network 412 may provide an adjustable input capacitance to the driver amplifier 414 or to the power amplifier 424. The exemplary embodiment of the programmable input matching network 412 shown in FIG. 7 comprises switchable series capacitances 702 and 706. The capacitance 702 may be engaged by a switch 704, and the capacitance 706 may be engaged with a switch 708. The exemplary embodiment of the programmable input matching network 412 shown in FIG. 7 further comprises switchable parallel capacitances 703 and 705. The capacitance 703 may be engaged by a switch 707, and the capacitance 705 may be engaged with a switch 709. In an exemplary embodiment, the switches 704, 708, 707 and 709 may be programmed or controlled by a control signal from the PA mode control circuit 375, or another control signal from the data processor 310 (FIG. 3), compliant with, for example, the mobile industry processor interface (MIPI) communication protocol and interface. The programmable input matching network 412 also comprises an inductance 711 and a series capacitance 713.

Although two instances of switchable series capacitances and two instances of switchable parallel capacitances are shown in FIG. 7, more or fewer switchable series and switchable parallel capacitances may be implemented in the programmable input matching network 412, depending on the range of capacitance desired. Moreover, only switchable series capacitances, or only switchable parallel capacitances may also be implemented instead of, or in addition to, the combination of switchable series capacitances and switchable parallel capacitances shown in FIG. 7.

In an exemplary embodiment, the driver amplifier 414 may comprise transistors 710 and 712. A bias circuit 714 may comprise transistors 716 and 718, and resistor 719. The transistors 716 and 712 may be biased at their respective gates with bias voltages Vg1 and Vg2, respectively. The driver amplifier 414 may also comprise capacitors 720 and 722, resistor 721, and switch 725. In an exemplary embodiment, the RF input signal is provided to the gate of the transistor 710 on connection 432. A bias signal may also be provided from the bias circuit 714 to the gate of the transistor 710 on connection 432. An output of the driver amplifier 414 may be taken from the drain of the transistor 712 over connection 436.

In an exemplary embodiment, the bypass circuit 418 may comprise a switch 730 and a programmable or adjustable capacitance 732. In an exemplary embodiment, the switch 730 may be responsive to a control signal provided by the data processor 310 (e.g., PA mode control circuit 375) (FIG. 3). When the switch 730 is closed and the bypass circuit 418 is engaged (i.e., when the driver amplifier 414 is being bypassed for ULPM operation), the RF input signal on connection 432 is provided to the (non-programmable) interstage matching network 417 on connection 438 and then to the input of the power amplifier 424 on connection 439. The switch 725 and the resistor 721 form a feedback path to reduce the gain of the DA 414 when the switch 725 is closed. The switch 725 is open in bypass mode.

In an exemplary embodiment, the programmable interstage matching network 416 may provide an adjustable capacitance to adjust the impedance at the output of the driver amplifier 414 and, in conjunction with the interstage matching network 417, may provide an adjustable capacitance to adjust the impedance at the input of the power amplifier 424. The exemplary embodiment of the programmable interstage matching network 416 shown in FIG. 7 comprises switchable series capacitances 740 and 744. The capacitance 740 may be engaged with a switch 742, and the capacitance 744 may be engaged with a switch 746. The exemplary embodiment of the programmable interstage matching network 416 shown in FIG. 7 also comprises switchable parallel capacitances 743 and 745. The capacitance 743 may be engaged with a switch 747, and the capacitance 745 may be engaged with a switch 749. In an exemplary embodiment, the switches 742, 746, 747 and 749 may be programmed or controlled by a control signal from the data processor 310 (e.g., PA mode control circuit 375) (FIG. 3), compliant with, for example, the mobile industry processor interface (MIPI) communication protocol and interface.

In the exemplary embodiment shown in FIG. 7, the illustrated switched capacitances 703, 705, 740, 744, 743, and 745 can be used to adjust capacitance and/or prevent loading the impedance when switched off. In an exemplary embodiment, when the amplifier circuit 700 is operating in ULPM, that is, when the driver amplifier 414 and the interstage matching network 416 are bypassed, the capacitances 703, 705, 740, 744, 743, and 745 are removed from the amplifier circuit 700 to prevent any impedance loading. The removal of the capacitances 703, 705, 740, 744, 743, and 745 from the amplifier circuit 700 is shown using respective switches 707, 709, 742, 746, 747, and 749. However, other architectures for removing the effect of the capacitances 703, 705, 740, 744, 743, and 745 from the amplifier circuit 700 in ULPM are possible. In some exemplary embodiments, the capacitances 703, 705, 740, 744, 743, and 745 can be implemented as tunable, or variable capacitances, using, for example, voltage tunable capacitances, such as varactors. In other embodiments, tunable capacitances may be implemented using other means. If the capacitances 703, 705, 740, 744, 743, and 745 are implemented as banks of switched capacitors, for example, then so long as the effect of the capacitances can be removed from the amplifier circuit 700 in ULPM, the switches 707, 709, 742, 746, 747, and 749 may be omitted.

Although two instances of switchable series capacitances and two instances of switchable parallel capacitances are shown in FIG. 7, more or fewer switchable series and parallel capacitances may be implemented in the programmable interstage matching network 416, depending on the range of capacitance desired. Moreover, only switchable series capacitances, or only switchable parallel capacitances may also be implemented instead of, or in addition to, the combination of switchable series capacitances and switchable parallel capacitances shown in FIG. 7.

An output of the DC-DC converter 422 may be provided over connection 434 to an inductor 752 and a capacitor 754, and to the drain of the transistor 712 in the DA 414. In an exemplary embodiment, the DC supply voltage provided from the DC-DC converter 422 to the output of the driver amplifier 414 may be controlled according to the output power of the amplifier circuit 700. For example, the DC supply voltage provided from the DC-DC converter 422 to the output of the driver amplifier 414 may be reduced at certain power levels to improve the efficiency of the power amplifier circuit 700. In an exemplary embodiment, the supply voltage output, V_{DC_DC}, of the DC-DC converter 422 may track the power output, Pout, of the amplifier circuit 700 in HPM and may improve efficiency when the amplifier circuit 700 enters a backoff operating condition, where less than full power output is provided.

An output of the DC-DC converter 422 may also be provided over connection 434 to an inductor 753 and a capacitor 755 and to the collector of the transistor 760 in the power amplifier 424. In ULPM, minimizing the DC supply voltage, V_{DC_DC}, provided by the DC-DC converter 422 to the output of the power amplifier 424, based at least in part on the amplifier output power may improve efficiency of the power amplifier 424 under low power operation. For example, because the power output, Pout, of the power amplifier 424 is proportional to V_{DC-DC}², the supply voltage V_{DC-DC} can be reduced for low output power Pout. Since power added efficiency (PAE) PAE=Pout−Pin/VDC_DC*IDC_DC*100%, lower V_{DC_DC} translates to higher PAE since the output current, I_{DC_DC}, of the DC-DC converter 422 does not vary significantly with V_{DC_DC} for a given output power.

The power amplifier 424 may comprise one or more transistor stages, one of which is illustrated using reference numeral 760 with a capacitance 762 coupled to the base of the transistor 760, and is configured to receive the RF input signal over connection 439.

The bias circuit 419 provides a bias signal to the GaAs substrate 408 over connection 763. A bias circuit 764 may instead or in addition be located on the GaAs substrate 408 to provide additional bias voltage and current to the transistor 760.

The output of the power amplifier 424 is provided to the output matching network 410 over connection 442. The output of the output matching network 410 is provided to the output band select switch circuit 407 over connection 444. In an exemplary embodiment, the output band select switch circuit 407 may comprise a plurality of switches related to the output frequency band of the amplifier circuit 400. In the illustrated embodiment, all switches (or input paths) in the output band select switch circuit 407 receive the output of the output matching network 410.

In an alternative implementation, the power amplifier 424 can be divided into multiple sub cells to further improve ULPM performance, with no additional matching elements other than the output matching network 410 at the output of the power amplifier 424, thus minimizing output loss. For example, multiple instances of the transistor 760 could be coupled to the connection 439 as a common node, and individually coupled to multiple instances of the capacitor 762, where each instance of the transistor 760 could be controlled by an instance of the bias circuit 419 to turn the respective multiple instances of the transistor 760 on and off.

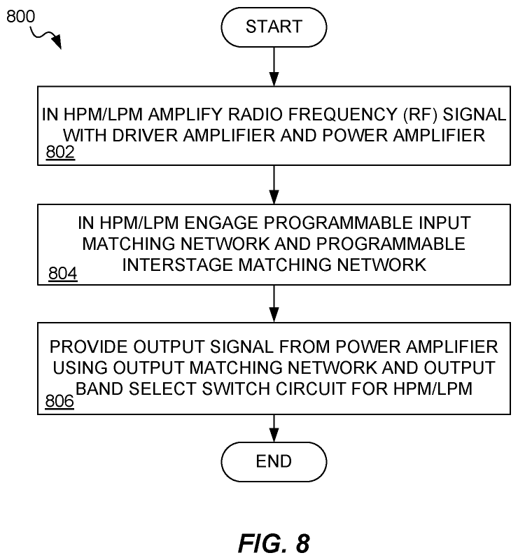

FIG. 8 is a flow chart 800 describing the operation of an exemplary embodiment of an amplifier circuit in accordance with an exemplary embodiment of the disclosure. The blocks in the method 800 can be performed in or out of the order shown, and in some embodiments, can be performed at least in part in parallel.

In block 802, in a high power mode or low power mode (HPM/LPM), an RF signal is amplified by a driver amplifier and a power amplifier. In an exemplary embodiment, the amplifier circuit 400 shown as configured in FIG. 5 may be used to amplify the RF input signal.

In block 804, a programmable input matching network and a programmable interstage matching network are engaged to provide input signal impedance matching for the driver amplifier, output impedance matching for the driver amplifier, and input impedance matching for the power amplifier. In an exemplary embodiment, the programmable input matching network 412 provides input signal impedance matching for the driver amplifier 414, and the programmable interstage matching network 416 provides output impedance matching for the driver amplifier 414, and input impedance matching for the power amplifier 424.

In block 806, an amplified RF output signal is provided from the power amplifier using an output matching network and an output band select switch circuit. In an exemplary embodiment, the RF output signal is provided from the power amplifier 424 using the output matching network 410 and the output band select switch circuit 407.

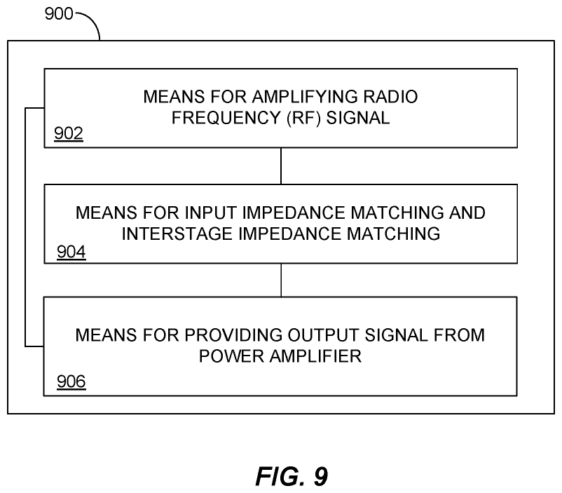

FIG. 9 is a functional block diagram of an apparatus 900 for an amplifier circuit in accordance with an exemplary embodiment of the disclosure. The apparatus 900 comprises means 902 for amplifying an RF signal. In certain embodiments, the means 902 for amplifying an RF signal can be configured to perform one or more of the functions described in operation block 802 of method 800 (FIG. 8). In an exemplary embodiment, the means 902 for amplifying an RF signal may comprise elements of the amplifier circuit 400, for example as shown as configured in FIG. 5 amplifying the RF input signal, such as the DA 414.

The apparatus 900 further comprises means 904 for input impedance matching and interstage impedance matching. In certain embodiments, the means 904 for input impedance matching and interstage impedance matching can be configured to perform one or more of the functions described in operation block 804 of method 800 (FIG. 8). In an exemplary embodiment, the means 904 for input impedance matching and interstage impedance matching may comprise the programmable input matching network 412 providing input signal impedance matching for the driver amplifier 414, and the programmable interstage matching network 416 providing output impedance matching for the driver amplifier 414, and input impedance matching for a power amplifier 424.

The apparatus 900 further comprises means 906 for providing an output signal from the power amplifier. In certain embodiments, the means 906 for providing an output signal from the power amplifier can be configured to perform one or more of the functions described in operation block 806 of method 800 (FIG. 8). In an exemplary embodiment, the means 906 for providing an output signal from the power amplifier may comprise the RF output signal being provided from the power amplifier 408 using the output matching network 410 and the output band select switch circuit 407.

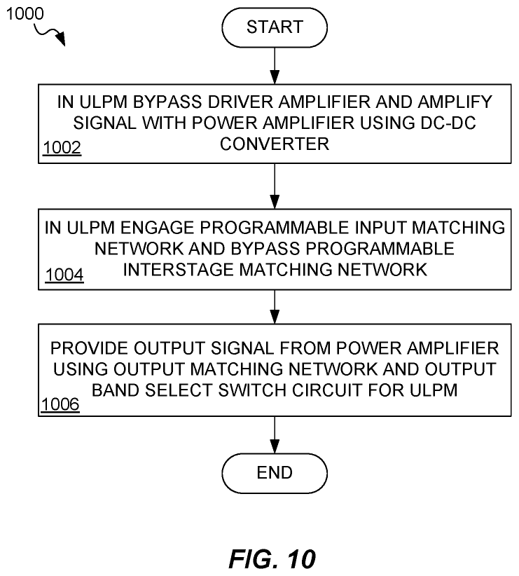

FIG. 10 is a flow chart 1000 describing the operation of an exemplary embodiment of an amplifier circuit in accordance with an exemplary embodiment of the disclosure. The blocks in the method 1000 can be performed in or out of the order shown, and in some embodiments, can be performed at least in part in parallel.

In block 1002, in an ultra-low power mode (ULPM), a driver amplifier is bypassed and an RF signal is amplified by a power amplifier using a DC-DC converter to provide a low DC supply voltage to the power amplifier. In an exemplary embodiment, the amplifier circuit 400 shown as configured in FIG. 6 may be used to amplify the RF input signal.

In block 1004, a programmable input matching circuit is engaged to provide input signal impedance matching for the power amplifier, while the programmable interstage matching circuit is bypassed. In an exemplary embodiment, the driver amplifier 414 and the programmable interstage matching network 416 are bypassed and the programmable input matching network 412 provides input signal impedance matching for the power amplifier 424.

In block 1006, an amplified RF output signal is provided from the power amplifier using an output matching network and an output band select switch circuit. In an exemplary embodiment, the RF output signal is provided from the power amplifier 424 using the output matching network 410 and the output band select switch circuit 407.

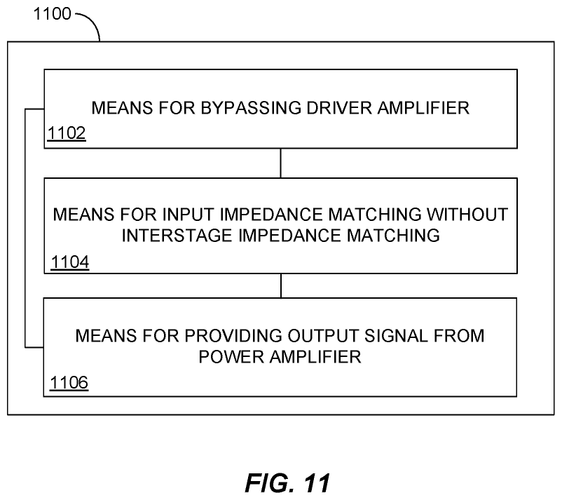

FIG. 11 is a functional block diagram of an apparatus 1100 for an amplifier circuit in accordance with an exemplary embodiment of the disclosure. The apparatus 1100 comprises means 1102 for bypassing a driver amplifier. In certain embodiments, the means 1102 for bypassing a driver amplifier can be configured to perform one or more of the functions described in operation block 1002 of method 1000 (FIG. 10). In an exemplary embodiment, the means 1102 for bypassing a driver amplifier may comprise elements of the amplifier circuit 400, for example as shown as configured in FIG. 6 amplifying the RF input signal, such as the DA bypass circuit 418.

The apparatus 1100 further comprises means 1104 for input impedance matching without interstage impedance matching. In certain embodiments, the means 1104 for input impedance matching can be configured to perform one or more of the functions described in operation block 1004 of method 1000 (FIG. 10). In an exemplary embodiment, the means 1104 for input impedance matching may comprise the programmable input matching network 412 providing input signal impedance matching for the power amplifier 424. In such a configuration, the driver amplifier 414 and the programmable interstage matching network 416 may be bypassed.

The apparatus 1100 further comprises means 1106 for providing an output signal from the power amplifier. In certain embodiments, the means 1106 for providing an output signal from the power amplifier can be configured to perform one or more of the functions described in operation block 1006 of method 1000 (FIG. 10). In an exemplary embodiment, the means 1106 for providing an output signal from the power amplifier may comprise the RF output signal being provided from the power amplifier 424 using the output matching network 410 and the output band select switch circuit 407.

The embodiments of the amplifier circuit described herein can be configured to provide a range of power amplification that reduces current consumption for two different power modes, for example for HPM/LPM and for ULPM.

The amplifier circuit described herein may be implemented on one or more ICs, analog ICs, RFICs, mixed-signal ICs, ASICs, printed circuit boards (PCBs), electronic devices, etc. The amplifier circuit described herein may also be fabricated with various IC device/process technologies such as complementary metal oxide semiconductor (CMOS), N-channel MOS (NMOS), P-channel MOS (PMOS), bipolar junction transistor (BJT), bipolar-CMOS (BiCMOS), heterojunction bipolar transistors (HBTs), high electron mobility transistors (HEMTs), silicon germanium (SiGe), gallium arsenide (GaAs), gallium nitride (GaN), silicon-on-insulator (SOI), etc.

An apparatus implementing the amplifier circuit described herein described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

Although selected aspects have been illustrated and described in detail, it will be understood that various substitutions and alterations may be made therein without departing from the spirit and scope of the present invention, as defined by the following claims.

What is claimed is:

1. An amplifier circuit, comprising:
a driver amplifier implemented on a silicon-on-insulator (SOI) substrate and configured to amplify a radio frequency (RF) signal;
a bypass circuit implemented on the SOI substrate and configured to selectively bypass the driver amplifier;
an output coupled to the driver amplifier and the bypass circuit;
an interconnect configured to couple the output to a gallium arsenide (GaAs) substrate; and
a power amplifier implemented on the GaAs substrate and configured to amplify a signal received over the interconnect from the output.

2. The amplifier circuit of claim 1, further comprising a programmable interstage matching network configured on the SOI substrate between the driver amplifier and the power amplifier, wherein the programmable interstage matching network is bypassed when the bypass circuit is conductive.

3. The amplifier circuit of claim 1, further comprising a DC-DC converter configured to provide a DC supply voltage to the power amplifier when in an ultra-low power mode (ULPM).

4. The amplifier circuit of claim 1, further comprising a programmable input matching network coupled to an input of the driver amplifier and the bypass circuit.

5. The amplifier circuit of claim 1, wherein the power amplifier comprises a plurality of power amplifier stages.

6. The amplifier circuit of claim 1, wherein an output path provides an amplified signal output in a high power mode/low power mode (HPM/LPM) and in an ultra-low power mode (ULPM).

7. The amplifier circuit of claim 6, wherein the output path comprises an output matching network coupled to an output of the power amplifier and an output band select switch circuit coupled to an output of the output matching network.

8. A method for communication, comprising:
in a first mode, amplifying a first communication signal using a driver amplifier on a silicon-on-insulator (SOI) substrate, providing the amplified first communication signal over an interconnect, and further amplifying the amplified first communication signal using a power amplifier on a gallium arsenide (GaAs) substrate; and
in a second mode, bypassing the driver amplifier to provide a second communication signal over the interconnect and amplifying the second communication signal using the power amplifier to the exclusion of the driver amplifier.

9. The method of claim 8, further comprising:
matching an impedance with a programmable interstage matching network on the SOI substrate between the driver amplifier and the power amplifier in the first mode; and
bypassing the interstage matching network in the second mode.

10. The method of claim 8, further comprising providing a DC supply voltage to the power amplifier using a DC-DC converter in the second mode.

11. The method of claim 8, further comprising:
impedance matching the first communication signal and the second communications signal using a programmable input matching network coupled to an input of the driver amplifier.

12. The method of claim 8, further comprising:
using an output path to provide the further amplified first communication signal and the amplified second communication signal.

13. The method of claim 12, wherein the output path comprises an output matching network coupled to an output of the power amplifier and an output band select switch circuit.

14. A device, comprising:
first means for amplifying an RF signal implemented on a silicon-on-insulator (SOI) substrate;
means for selectively bypassing the first means for amplifying;
means for controlling the bypass means;
first means for coupling an output to the first means for amplifying and the means for selectively bypassing;
second means for coupling the output to a gallium arsenide (GaAs) substrate; and
second means for amplifying a communication signal received over the second coupling means, the second means for amplifying implemented on the GaAs substrate.

15. The device of claim 14, further comprising:
means for impedance matching the communication signal between the first means for amplifying and the second means for amplifying; and
means for disabling the means for impedance matching when the second means for amplifying is used to amplify the communication signal to the exclusion of the first means for amplifying.

16. The device of claim 14, further comprising:
means for providing a DC supply voltage to the second means for amplifying when the second means for amplifying is used to amplify the communication signal to the exclusion of the first means for amplifying.

17. The device of claim 14, further comprising:
means for impedance matching the communication signal at an input of the first means for amplifying; and
means for impedance matching the amplified communication signal at an output of the second means for amplifying.

18. The device of claim 14, further comprising:
means for providing the amplified communication signal using an output path in a high power mode/low power mode (HPM/LPM) and in an ultra-low power mode (ULPM).

19. The device of claim 18, wherein the means for providing the amplified communication signal using an output path comprises an output matching network and an output band select switch circuit.

20. An amplifier, comprising:
a first amplifier circuit implemented on a first substrate and configured to selectively amplify a radio frequency (RF) signal in a first power mode;
a bypass circuit implemented on the first substrate and configured to bypass the first amplifier circuit in a second power mode, the second power mode operative to output a signal with lower power;
a shared output coupled to the first amplifier circuit and the bypass circuit;
a shared interconnect configured to couple the output to a second substrate; and
a shared second amplifier circuit implemented on a second substrate, the second amplifier circuit being configured to amplify the RF signal in the first power mode and the second power mode.

21. The amplifier of claim 20, further comprising a programmable input matching network shared by the first amplifier circuit and the bypass circuit.

22. The amplifier of claim 20, wherein the second amplifier circuit comprises a plurality of power amplifier stages.

23. The amplifier of claim 20, wherein a shared output path provides an amplified signal output in the first power mode and the second power mode.

24. The amplifier of claim 23, wherein the output path comprises an output matching network and an output band select switch circuit.

25. The amplifier of claim 20, wherein the first substrate is a silicon-on-insulator (SOI) substrate and the second substrate is a gallium arsenide (GaAs) substrate.
